(19) United States
(12) Patent Application Publication
(10) Pub. No.: US 2004/0198052 A1
(43) Pub. Date: Oct. 7, 2004

(54) Apparatus for manufacturing semiconductor device

(76) Inventors: Tetsuji Togawa, Chigasaki-shi (JP); Nobuyuki Takada, Fujisawa-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/827,237

(22) Filed: Apr. 20, 2004

Related U.S. Application Data
(62) Division of application No. 09/358,252, filed on Jul. 20, 1999.

(30) Foreign Application Priority Data
Jul. 21, 1998 (JP) 221100/1998

(51) Int. Cl. H01L 21/302; H01L 21/461

(52) U.S. Cl. 438/689

(57) ABSTRACT

An apparatus is used for manufacturing semiconductor device, and the apparatus is not required to be installed in a clean room and is capable of processing semiconductor wafers in a clean atmosphere without exposure to external environments. The apparatus comprises an enclosing structure defining a closed space isolated from an external environment, a purifying system for keeping the closed space clean, a processing device disposed in the closed space for processing a semiconductor wafer, and a pressure elevating device for keeping an internal pressure high in the closed space so as to be higher than a pressure in the external environment.

### BACKGROUND OF THE INVENTION

1. Field of the Invention

The present invention relates to an apparatus for manufacturing semiconductor device, and more particularly to an apparatus for manufacturing semiconductor device which is not required to be installed in a clean room and is capable of processing semiconductor wafers in a clean atmosphere without exposure to external environments.

2. Description of the Related Art

In manufacturing semiconductor devices, fine particles such as dust particles in the air affect both the quality of products and the yield of products. Therefore, various processes of the semiconductor device fabrication are carried out in a clean room in which dust particles in the air are removed to extremely high level.

However, since a clean room used for the fabrication of semiconductor devices takes up a relatively large space area, installation of a clean room incurs a considerable initial cost. In addition, a considerable running cost is required to keep the entire clean room at a desired level of cleanliness continuously. The clean room is well suited for the purpose of creating a large clean space and maintaining the large clean space under the same environment in its entirety. However, if it is necessary for various different processes of the semiconductor device fabrication to create different atmospheres or environments, then the clean room is unsuited for creating such different individual atmospheres or environments.

### SUMMARY OF THE INVENTION

It is therefore an object of the present invention to provide an apparatus for manufacturing semiconductor device which is not required to be installed in a clean room and is capable of processing semiconductor wafers in a clean atmosphere without exposure to external environments.

In order to achieve the above object, according to the present invention, there is provided an apparatus for manufacturing semiconductor device comprising: an enclosing structure defining a closed space isolated from an external environment; a purifying system for keeping the closed space clean; a processing device disposed in the closed space for processing a semiconductor wafer; and a pressure elevating device for keeping an internal pressure high in the closed space so as to be higher than a pressure in the external environment.

The enclosing structure keeps the closed space isolated from the external environment, and the internal pressure in the closed space is maintained at a level higher than the pressure in the external environment to maintain a desired level of cleanliness in the closed space. Therefore, the apparatus can be installed in its entirety in the external environment whose contaminated level is similar to those in ordinary room spaces. The enclosing structure may comprise a housing.

Consequently, the apparatus is not required to be installed in a clean room, and can process semiconductor wafers in a clean atmosphere without exposure to the external environment. Even if the apparatus is installed in the external environment, the closed space therein can be kept at the same level of cleanliness as in usual clean rooms used for semiconductor fabrication. The apparatus for manufacturing semiconductor device may preferably comprise a polishing apparatus.

The above and other objects, features, and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a perspective view of a polishing apparatus as an apparatus for manufacturing semiconductor device according to the present invention;

FIG. 2 is a plan view of an internal structure of the polishing apparatus shown in FIG. 1;

FIG. 3A is a schematic perspective view of a purifying system in the polishing apparatus;

FIG. 3B is a perspective view of a filter unit of the purifying system;

FIG. 4A is a plan view of a layout of a polishing apparatus shown in FIGS. 1 through 3A and 3B;

FIG. 4B is a plan view of another layout of polishing apparatus shown in FIGS. 1 through 3A and 3B;

FIG. 5 is an elevational view of a purifying system in the polishing apparatus; and

FIG. 6 is an elevational view of a purifying system in the polishing apparatus.

### DETAILED DESCRIPTION OF THE PREFERRED EMBODIMENTS

The principles of the present invention are particularly useful when embodied in a polishing apparatus for polishing semiconductor wafers.

Recent rapid progress in semiconductor device integration demands smaller and smaller wiring patterns or interconnections and also narrower spaces between interconnections which connect active areas. One of the processes available for forming such interconnection is photolithography. Though the photolithographic process can form interconnections that are at most 0.5 μm wide, it requires that surfaces on which pattern images are to be focused by a stepper be as flat as possible because the depth of focus of the optical system is relatively small. However, conventional apparatuses for planarizing semiconductor wafers such as a self-planarizing CVD apparatus or an etching apparatus fail to produce completely flat surfaces on semiconductor wafers. Recently, it has been attempted to planarize semiconductor wafers with a polishing apparatus which is expected to achieve complete planarization of the semiconductor wafers with greater ease than the above conventional apparatuses. Such a process is called Chemical Mechanical Polishing (CMP) in which the semiconductor wafers having semiconductor devices thereon are chemically and mechanically polished while supplying an abrasive liquid comprising abrasive grains and chemical solution such as alkaline solution.

A polishing apparatus as an apparatus for manufacturing semiconductor devices according to the present invention will be described below.

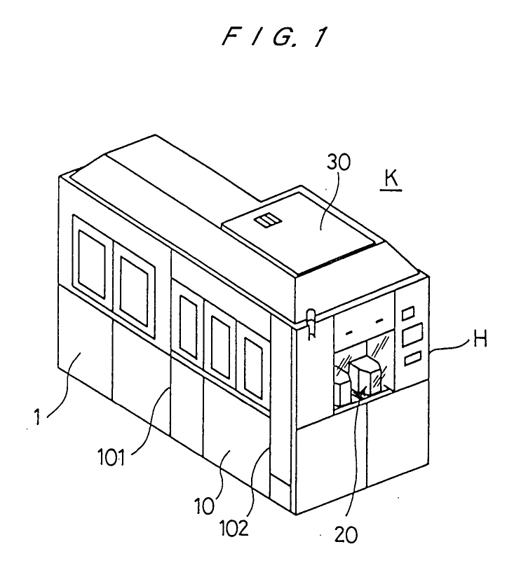

As shown in FIG. 1, the polishing apparatus is provided with a housing H, and the interior of the polishing apparatus is isolated from an external environment K which is an ordinary environment that is not treated by any purifying system. That is, the external environment K is different from the internal environment of the clean room and is not kept clean. The housing H constitutes an enclosing structure capable of containing and preventing an atmosphere within the enclosing structure from escaping therefrom to the exterior environment K.

The polishing apparatus comprises a polishing section 1, a cleaning section 10, and a loading/unloading section 20. The polishing section 1 and the cleaning section 10 are separated from each other by a partition 101, and the cleaning section 10 and the loading/unloading section 20 are separated from each other by a partition 102. Semiconductor wafers are transferred between adjacent ones of these sections through openings (not shown) defined in the partitions 101, 102.

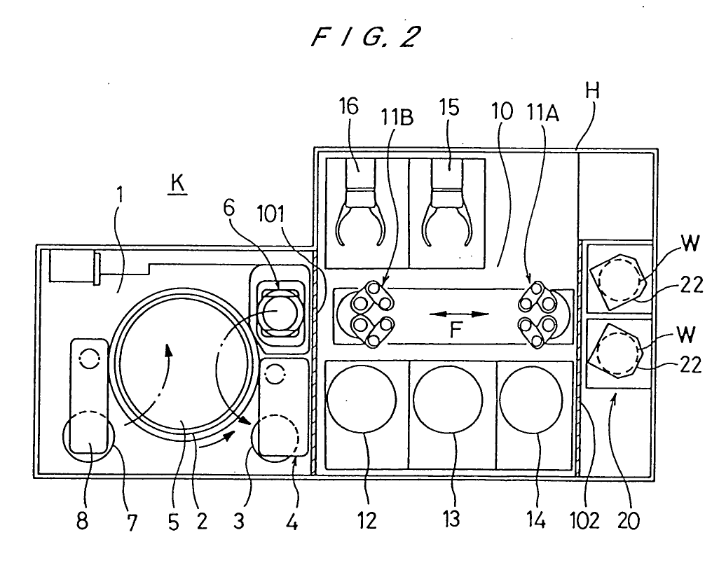

FIG. 2 shows in plan an internal structure of the polishing apparatus shown in FIG. 1. The polishing section 1 comprises a turntable 2, and a top ring unit 4 which has a top ring 3 for holding a semiconductor wafer and pressing the semiconductor wafer against the turntable 2. The turntable 2 is coupled to an electric motor (not shown) and can be rotated about its own axis in the direction indicated by the arrow by the electric motor. A polishing cloth 5 comprising, e.g., IC-1000 manufactured by Rodel, Inc., is attached to the upper surface of the turntable 2.

The top ring unit 4 is angularly movable to selectively place the top ring 3 in a transfer position over a pusher 6 for transferring a semiconductor wafer to and from the top ring 3, a polishing position over the turntable 2, and a standby position off the turntable 2. The top ring 3 is coupled to an electric motor and a lifting/lowering cylinder (both not shown). The top ring 3 can be rotated about its own axis by the electric motor, and can be lifted and lowered along a vertical axis by the lifting/lowering cylinder for pressing the semiconductor wafer against the polishing cloth 5 under a desired pressure. The semiconductor wafer is held by a lower surface of the top ring 3 under a vacuum. An abrasive liquid supply nozzle (not shown) is positioned above the turntable 2 for supplying an abrasive liquid to the polishing cloth 5 on the turntable 2.

The polishing section 1 also has a dressing unit 8 having a dresser 7. The dressing unit 8 is angularly movable to selectively bring the dresser 7 to a dressing position over the turntable 2 and a standby position off the turntable 2. The dresser 7 is coupled to an electric motor and a lifting/lowering cylinder (both not shown), and can be rotated about its own axis by the electric motor and lifted and lowered along a vertical axis by the lifting/lowering cylinder.

In the polishing section 1 having the above structure, a semiconductor wafer is held by the top ring 3 and pressed against the polishing cloth 5. While the turntable 2 and the top ring 3 are rotated, the lower surface of the semiconductor wafer is brought in sliding contact with the polishing cloth 5. At this time, an abrasive liquid is supplied onto the polishing cloth 5 by the abrasive liquid supply nozzle. Therefore, the lower surface of the semiconductor wafer is polished by a combination of a mechanical action of fine abrasive grain particles contained in the abrasive liquid and a chemical action of an alkaline or acid solution contained in the abrasive liquid.

When the predetermined amount of material is polished and removed from the semiconductor wafer, the polishing process is completed. After completing the polishing process, since the characteristics of the polishing cloth 5 change and the polishing capability of the polishing cloth 5 is deteriorated, the polishing cloth 5 is dressed by the dressing unit 8.

The cleaning section 10 comprises two transfer devices 11A, 11B such as robots disposed in a central region thereof, a primary cleaning machine 12, a secondary cleaning machine 13, a spin drier 14, and a pair of reversing machines 15, 16 for reversing semiconductor wafers. The loading/unloading section 20 disposed adjacent to the cleaning section 10 remotely from the polishing section 1 has a pair of wafer cassettes 22 placed therein. A semiconductor wafer W in one of the wafer cassettes 22 is taken out by the transfer device 11A and transferred to the reversing machine 15. After the semiconductor wafer W is reversed by the reversing machine 15, the semiconductor wafer W is transferred by the transfer device 11B to the pusher 6 in the polishing section 1.

The semiconductor wafer W is then polished in the polishing section 1, and the polished semiconductor wafer W is transferred by the transfer device 11B to the reversing machine 16. After the semiconductor wafer W is reversed by the reversing machine 16, the semiconductor wafer W is fed successively to and cleaned by the primary and secondary cleaning machines 12, 13, and then transferred to and dried by the spin drier 14. The polished and cleaned semiconductor wafer W is returned to the wafer cassette 22 in the loading/unloading section 20.

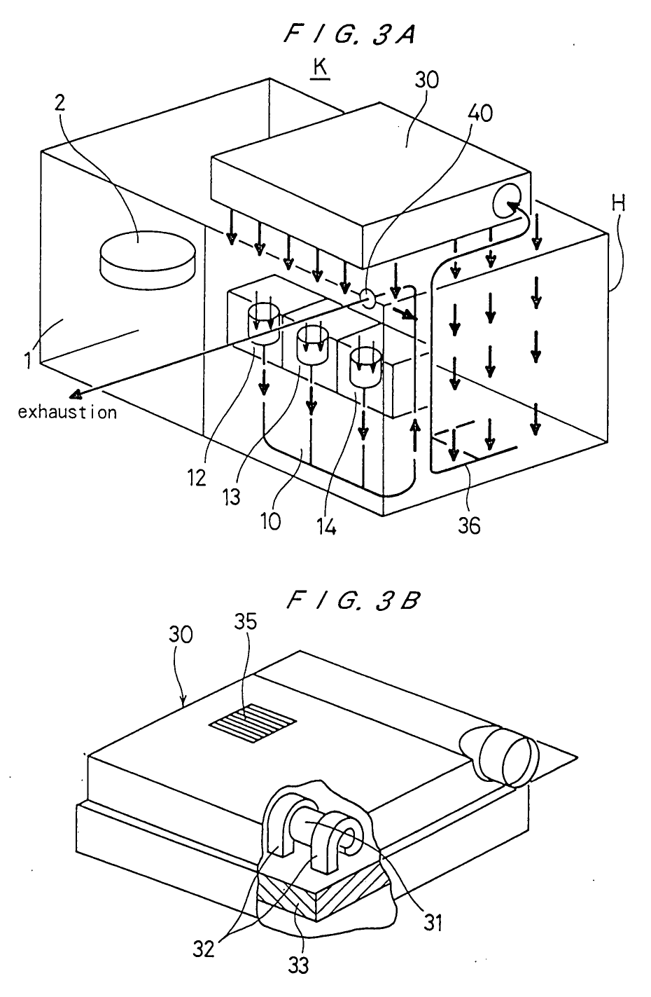

FIGS. 3A and 3B show a cleaning system or purifying system in the polishing apparatus. The purifying system is schematically shown in its entirety in FIG. 3A, and a filter unit of the purifying system is shown in FIG. 3B. The loading/unloading section 20 is omitted from illustration in FIG. 3A.

A filter unit 30 is mounted on a ceiling of the cleaning section 10. The filter 30 serves both to clean or purify air in the cleaning section 10 and to generate a downflow of air in the cleaning section 10.

Air in the cleaning section 10 is purified when it is forced to flow through a filter 33 in the filter unit 30 by a fan 32 driven by a motor 31. The rotational speed of the fan 32 can be changed by the motor 31 depending on an air flow rate that is required to flow in the cleaning section 10. In this manner, air in the cleaning machines 12, 13, the spin drier 14, and the reversing machines 15, 16 is continuously discharged. The rate of air discharged from the cleaning section 10 is adjusted by a damper 40 that is disposed in a wall of the housing H. The air pressure in the cleaning section 10 is adjusted so as to be slightly higher than the atmospheric pressure by introducing air from an air inlet 35 in the filter unit 30 at a rate slightly greater than the rate of air discharged from the cleaning section 10. The air introduced from the air inlet 35 is purified when the air flows through the filter 33, and then supplied into the cleaning section 10. If chemicals are used in the cleaning section 10 to clean the semiconductor wafers which have been polished, then the filter 33 may be combined with a chemical filter. The chemical filter may adsorb chemicals contained in the air.

A downflow of clean air needs to be created in the cleaning section 10. Upper areas of the cleaning machines 12, 13, the spin drier 14, and the region where semiconductor wafers are conveyed in the cleaning section 10 are covered with an air outlet of the filter 33. Air in the cleaning section 10 is drawn into a return duct in a lower base of the polishing apparatus and flows through a return duct 36 back into the filter 33, so that the air circulates through the cleaning section 10.

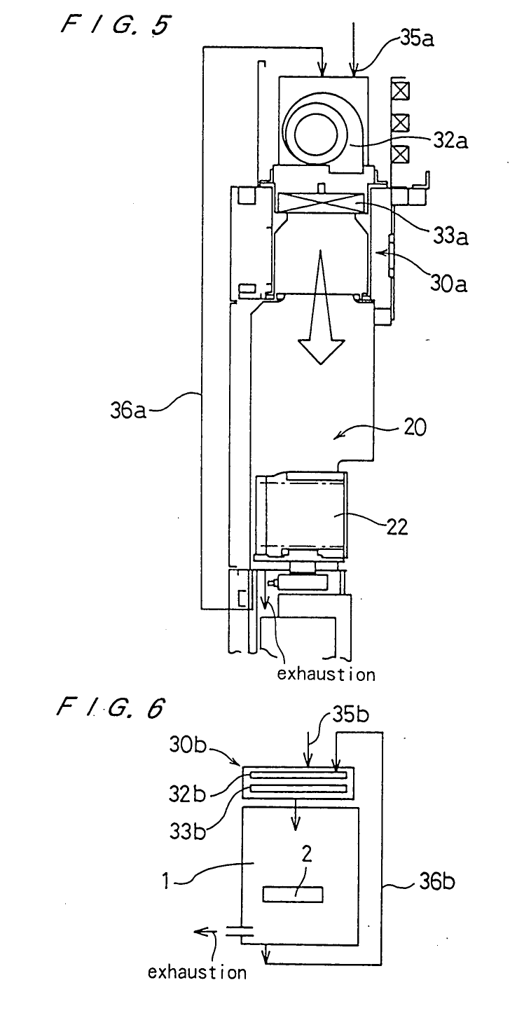

FIGS. 5 and 6 show purifying systems for keeping the internal pressure in the loading/unloading section 20 and the polishing section 1 higher than the pressure outside of the polishing apparatus to maintain the interior space clean.

The purifying systems shown in FIGS. 5 and 6 are essentially the same as the purifying system shown in FIGS. 3A and 3B. Those parts of the purifying systems shown in FIGS. 5 and 6 which correspond to those of the purifying system shown in FIGS. 3A and 3B are denoted by identical reference numerals with suffixes “a”, “b”. Specifically, the purifying systems shown in FIGS. 5 and 6 have filter units 30a, 30b, fans 32a, 32b, filters 33a, 33b, air inlets 35a, 35b, and return ducts 36a, 36b which are associated with the loading/unloading section 20 and the polishing section 1, respectively. The purifying systems shown in FIGS. 5 and 6 operate in essentially the same manner as the purifying system shown in FIGS. 3A and 3B. The rate of air discharged from the loading/unloading section 20 and the polishing section 1 is adjusted by dampers (not shown) in the same manner as the purifying system shown in FIGS. 3A and 3B.

The internal pressure in the loading/unloading section 20 is the highest, the internal pressure in the cleaning section 10 is the second highest, and the internal pressure in the polishing section 1 is the lowest. This is because the cleanliness needs to be kept in levels higher successively in the polishing section 1, the cleaning section 10, and the loading/unloading section 20 in the order named.

Even when the cleaning section 10, the loading/unloading section 20, and the polishing section 1 communicate with each other, air flows only from a higher-pressure space toward a lower-pressure space. Since there is no air flow from a less clean space toward a cleaner space, the cleaning section 10, the loading/unloading section 20, and the polishing section 1 are prevented from contaminating each other. The internal pressure in the polishing section 1 is kept higher than the atmospheric pressure by about 0.001 kg/cm². Since air does not flow from the outside of the polishing apparatus into the polishing section 1, the cleaning section 10, and the loading/unloading section 20, these sections will not be contaminated by external environments even when the polishing apparatus is installed in contaminated areas.

Inasmuch as desired levels of cleanliness are kept in the cleaning section 10, the loading/unloading section 20 and the polishing section 1, even if the polishing apparatus is installed in a clean room, the polishing apparatus will not contaminate the clean room. Consequently, the polishing apparatus may be installed in a clean room. Furthermore, because the polishing section 1 does not need to keep air therein as clean as the cleaning section 10 and the loading/unloading section 20, it is not necessary in some cases to positively clean the air in the polishing section 1 by forced circulation through the return duct 36b shown in FIG. 6.

In the polishing section 1 shown in FIG. 6, the rate of air discharged from the polishing section 1 may be increased, or the rate of air introduced from the air inlet 35b may be reduced, to make the internal pressure in the polishing section 1 lower than the pressure outside of the polishing apparatus. Though this internal pressure setting allows air to flow from the outside of the polishing apparatus into the polishing section 1, the inflow of air may not cause any significant problem in the polishing section 1 because of less strict requirements to keep air clean in the polishing section 1 than in the cleaning section 10 and the loading/unloading section 20. In this case, the internal pressure in the cleaning unit 10 is set to be kept higher than the atmospheric pressure by about 0.001 kg/cm².

In order to keep the housing H hermetically sealed sufficiently, gaskets (not shown) are provided in openings such as door openings in the housing H and on mating surfaces of the sections.

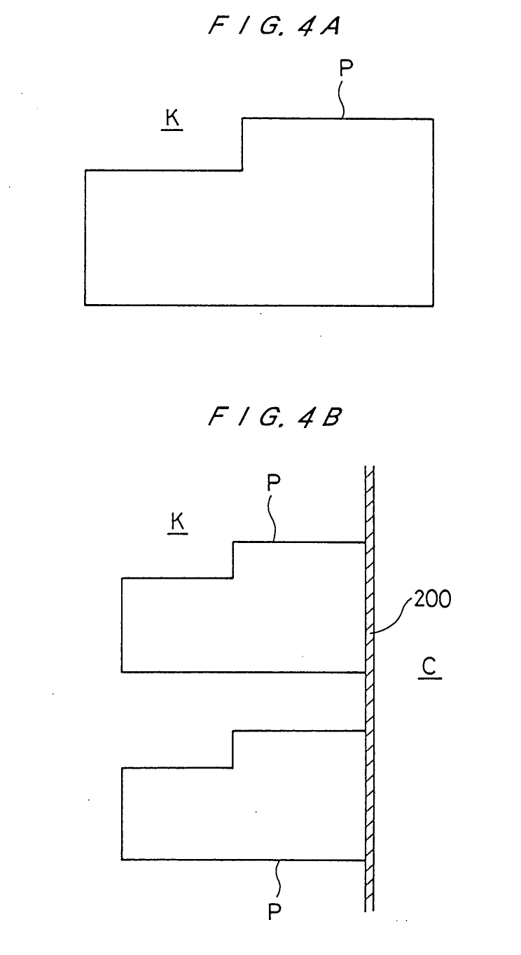

FIGS. 4A and 4B show different layouts of the polishing apparatus P shown in FIGS. 1, 2, and 3A, 3B.

In FIG. 4A, the polishing apparatus P is singly installed in a location exposed to the external environment K. In order to supply semiconductor wafers to and remove semiconductor wafers from the polishing apparatus P, a transfer device (not shown) having a clean box for storing semiconductor wafers, e.g., SMIF pod manufactured by Asyst Technologies, Inc., is connected to the polishing apparatus P for allowing semiconductor wafers to be polished by the polishing apparatus P without exposure to the external environment K. The transfer device is arranged to supply an unpolished semiconductor wafer to the polishing apparatus, receive a polished semiconductor wafer from the polishing apparatus, and feed the polished semiconductor wafer to a next process.

In FIG. 4B, two polishing apparatuses P are installed in a location exposed to the external environment K and positioned adjacent to a partition wall 200 of a clean room C. Semiconductor wafers to be polished are supplied from the interior of the clean room C to the polishing apparatuses P through openings (not shown) defined in the partition wall 200, and polished and cleaned semiconductor wafers are returned from the polishing apparatuses P through the openings in the partition wall 200 back into the interior of the clean room C where the returned semiconductor wafers are delivered to a next process.

In the illustrated embodiment, the interior space of the polishing apparatus is kept clean by an air circulation system for circulating air through the filter unit and the polishing apparatus. However, clean air may be introduced from the outside of the polishing apparatus into the polishing apparatus, and contaminated air may be discharged from the polishing apparatus. In such a modification, the internal pressure in the polishing apparatus may be adjusted so as to be higher than the pressure outside of the polishing apparatus by regulating the rate of clean air supplied to the polishing apparatus and the rate of contaminated air discharged from the polishing apparatus.

Although certain preferred embodiments of the present invention have been shown and described in detail, it should be understood that various changes and modifications may be made therein without departing from the scope of the appended claims.

1-8 (Cancelled)

9. A method for manufacturing a semiconductor device, comprising:
providing a manufacturing apparatus in an external environment;
isolating from said external environment a closed space that is defined by an enclosing structure of said manufacturing apparatus;
maintaining a clean atmosphere within said closed space by operating a purifying system;
processing a semiconductor wafer within said closed space by operating a processing device; and
maintaining an internal pressure of said closed space to be higher than a pressure in said external environment by operating a pressure elevating device.

10. The method according to claim 9, wherein said enclosing structure comprises a housing.

11. The method according to claim 9, wherein said purifying system comprises a filter unit mounted on said enclosing structure, and further comprising supplying clean air into said closed space by operating said filter unit.

12. The method according to claim 11, wherein maintaining the internal pressure of said closed space to be higher than the pressure in said external environment comprises operating a fan disposed in said filter unit and also operating a damper to control a rate at which air is discharged from said closed space.

13. The method according to claim 9, wherein processing the semiconductor wafer comprises polishing said semiconductor wafer with a polishing device.

14. The method according to claim 9, wherein processing the semiconductor wafer comprises polishing said semiconductor wafer in a polishing section to provide a polished semiconductor wafer and cleaning said polished semiconductor wafer in a cleaning section to provide a cleaned semiconductor wafer, and further comprising controlling an internal pressure of said cleaning section to be higher than an internal pressure of said polishing section.

15. The method according to claim 14, further comprising:
receiving said semiconductor wafer in a loading/unloading section prior to polishing said semiconductor wafer;
receiving said cleaned semiconductor wafer in said loading/unloading section; and
controlling an internal pressure of said loading/unloading section to be higher than said internal pressure of said cleaning section.

16. The method according to claim 14, wherein a partition having an opening partitions said cleaning section from said polishing section, and further comprising transferring said polished semiconductor wafer through said opening from said polishing section to said cleaning section.

17. A method for processing a semiconductor wafer, comprising:
polishing a semiconductor wafer in a polishing section of a processing apparatus to provide a polished semiconductor wafer;
controlling an internal pressure of said polishing section to be higher than a pressure exterior of said processing apparatus;
discharging said polished semiconductor wafer from said polishing apparatus through an unloading section; and
controlling an internal pressure of said unloading section to be higher than said pressure exterior of said processing apparatus.

18. The method according to claim 17, further comprising transferring said semiconductor wafer prior to being polished from said unloading section to said polishing section.

19. The method according to claim 17, further comprising cleaning and then drying said polished semiconductor wafer in a cleaning section to provide a cleaned semiconductor wafer.

20. The method according to claim 19, further comprising controlling said internal pressure of said unloading section to be higher than an internal pressure of said cleaning section.

21. The method according to claim 19, further comprising controlling said internal pressure of said cleaning section to be higher than said internal pressure of said polishing section.

22. The method according to claim 19, wherein said polishing section, said cleaning section and said unloading section are separated from each other by partitions, and further comprising:
transferring said semiconductor wafer prior to being polished from said unloading section to said polishing section through one of said partitions;
transferring said polished semiconductor wafer from said polishing section to said cleaning section through another of said partitions; and
transferring said cleaned semiconductor wafer from said cleaning section to said unloading section through said one of said partitions.

23. A method for processing a semiconductor wafer, comprising:
polishing a semiconductor wafer in a polishing section of a processing apparatus to provide a polished semiconductor wafer;
cleaning and then drying said polished semiconductor wafer in a cleaning section to provide a cleaned semiconductor wafer;
controlling an internal pressure of said cleaning section to be higher than a pressure exterior of said processing apparatus;
discharging said polished semiconductor wafer from said processing apparatus through an unloading section; and
controlling an internal pressure of said unloading section to be higher than said pressure exterior of said processing apparatus.

24. The method according to claim 23, further comprising controlling said internal pressure of said unloading section to be higher than said internal pressure of said cleaning section.

25. A method for manufacturing a semiconductor device, comprising:
providing a manufacturing apparatus in an external environment;
isolating from said external environment a closed space that is defined by an enclosing structure of said manufacturing apparatus;
maintaining a clean atmosphere within said closed space by operating a purifying system;
processing a semiconductor wafer within said closed space by operating a processing device; and
controlling an environment in said closed space to be cleaner than said external environment.

26. The method according to claim 25, wherein said enclosing structure comprises a housing.

27. The method according to claim 25, wherein said purifying system comprises a filter unit mounted on said enclosing structure, and further comprising supplying clean air into said closed space by operating said filter unit.

28. The method according to claim 25, wherein processing the semiconductor wafer comprises polishing said semiconductor wafer with a polishing device.

29. The method according to claim 25, wherein processing the semiconductor wafer comprises polishing said semiconductor wafer in a polishing section to provide a polished semiconductor wafer and cleaning said polished semiconductor wafer in a cleaning section.
